(19) United States
(12) Patent Application Publication
(10) Pub. No.: US 2025/0079152 A1
(43) Pub. Date: Mar. 6, 2025

(54) SUBSTRATE PROCESSING METHOD AND SUBSTRATE PROCESSING SYSTEM

(71) Applicant: SCREEN Holdings Co., Ltd., Kyoto (JP)

(72) Inventor: Noritake SUMI, Kyoto (JP)

(21) Appl. No.: 18/679,553

(22) Filed: May 31, 2024

(30) Foreign Application Priority Data
Aug. 28, 2023 (JP) 2023-138194

(51) Int. Cl. H01L 21/02; B08B 3/08; B08B 3/10; B08B 7/00; H01L 21/67

(52) U.S. Cl. CPC H01L 21/02101; B08B 3/08; B08B 3/10; B08B 7/0021; H01L 21/67034

(57) ABSTRACT

In a substrate processing method and substrate processing, a preliminary organic solvent supply processing is performed between a chemical processing and a rinse processing. After the rinse processing, a replacement processing using an organic solvent and a liquid fill processing (liquid film formation processing) is performed to form a liquid film. The rinse liquid remains not on the inner bottom surface of the pattern, but at a position sandwiched by two types of liquid layers in a vertical direction. The rinse liquid comprising a remaining liquid diffuses with those liquid layers and becomes a so-called remaining liquid-free state. Under that state, a dry processing by the processing fluid in the supercritical state is performed.

### CROSS REFERENCE TO RELATED APPLICATION

The disclosure of Japanese Patent Application No. 2023-138194 filed on Aug. 28, 2023 including specification, drawings and claims is incorporated herein by reference in its entirety.

### BACKGROUND OF THE INVENTION

### 1. Field of the Invention

This invention relates to a technique for drying a substrate in a processing chamber and particularly to a process for processing a substrate covered with a liquid film by a processing fluid in a supercritical state.

### 2. Description of the Related Art

Processing steps of various substrates such as semiconductor substrates and glass substrates for display device include processing of a substrate surface by various processing fluids. A wet processing using a liquid such as a chemical or a rinse liquid as a processing fluid has been conventionally widely performed. In recent years, a processing using a processing fluid in a supercritical state has also been put to practical use to dry the substrate after this wet processing. Particularly, this is useful in a dry processing of a substrate having a pattern formed surface formed with a fine pattern. This is because the processing fluid in the supercritical state has a property of having a lower surface tension than liquids and entering deep into gaps of the pattern. By using this processing fluid, the dry processing can be efficiently performed. Further, it is also possible to reduce an occurrence risk of pattern collapse due to a surface tension during drying.

For example, in a substrate processing system described in JP 2013-201302A, a substrate developing device is provided as an example of a “wet processing device” of the invention. In this substrate developing device, an IPA (isopropyl alcohol) liquid, which is an example of an “organic solvent” of the invention, is supplied to a substrate wetted with a rinse liquid as a final processing in this device. In this way, IPA replacement is performed and the rinse liquid is removed from the surface of the substrate. Further, a liquid-filled state is created by filling the IPA liquid on the surface of the substrate. That is, a liquid film containing the IPA liquid is formed into a puddle shape. As a result, the surface of the substrate is maintained in a state wetted with the IPA liquid. Then, the substrate maintained in the liquid-filled state is conveyed to a substrate drying device corresponding to an example of a “supercritical processing device” of the invention by a substrate conveying device, and a dry processing by a processing fluid in a supercritical state is performed.

### SUMMARY OF INVENTION

In a wet processing device such as a substrate developing device or a substrate cleaning device, a liquid such as a rinse liquid is desirably completely discharged from the inside of a pattern by IPA replacement. However, the liquid may remain on the inner bottom surface of the pattern. If the substrate is carried into a substrate drying device (supercritical processing device) while the liquid remaining in this way (hereinafter, referred to as a “remaining liquid”) is left unremoved and a supercritical dry processing is performed, the following problem may occur. That is, the replacement of a liquid component constituting a liquid film and a processing fluid in a supercritical state tends to be incomplete. Thus, a measure for increasing a use amount of the processing fluid is thought to cover that problem. However, this leads to an increase of running cost and gives a large environmental burden on the society.

Further, even if the use amount of the processing fluid was increased, the remaining liquid might have remained on the inner bottom surface of the pattern and caused pattern collapse. Thus, the presence of the remaining liquid is one of main factors for reducing a product yield.

This invention was developed in view of the above problem and aims to provide a technique capable of improving a yield while reducing an environmental burden by reducing the consumption of a processing fluid in a substrate processing system for conveying a substrate in a state filled with an organic solvent on a surface of the substrate subjected to a wet processing from a wet processing device to a supercritical processing device and drying the substrate using a processing fluid in a supercritical state.

One aspect of this invention is directed to a substrate processing method for processing a substrate having a pattern formed surface formed with a pattern. The method comprises: (a) performing a chemical processing of the substrate by supplying a chemical to the pattern formed surface, a preliminary organic solvent supply processing by supplying an organic solvent to the pattern formed surface, a rinse processing by supplying a rinse liquid to the pattern formed surface, a replacement processing by supplying the organic solvent to the pattern formed surface and a liquid fill processing by supplying the organic solvent on the pattern formed surface in this order in a wet processing device; (b) conveying the substrate from the wet processing device to a supercritical processing device while a liquid-filled state of the organic solvent on the pattern formed surface by the liquid fill processing is kept; and (c) drying the substrate by bringing a processing fluid in a supercritical state into contact with the pattern formed surface in the liquid-filled state in the supercritical processing device.

Other aspect of the invention is a substrate processing system for processing a substrate having a pattern formed surface formed with a pattern. The system comprises: a wet processing device configured to perform a chemical processing, a preliminary organic solvent supply processing, a rinse processing, a replacement processing and a liquid fill processing in this order, the chemical processing being of supplying a chemical to the pattern formed surface, the preliminary organic solvent supply processing being of supplying an organic solvent to the pattern formed surface, the rinse processing being of supplying a rinse liquid to the pattern formed surface, the replacement processing being of supplying the organic solvent to the pattern formed surface, the liquid fill processing being of creating a liquid-filled state filled with the organic solvent on the pattern formed surface; a supercritical processing device configured to dry the substrate by bringing a processing fluid in a supercritical state into contact with the pattern formed surface in the liquid-filled state; and a substrate conveying device configured to convey the substrate in the liquid-filled state from the wet processing device to the supercritical processing device.

Conventionally, the rinse processing, the replacement processing and the liquid fill processing are performed in this order after the chemical processing is performed by supplying the chemical to the pattern formed surface in the wet processing device. Thus, the rinse liquid may remain on the inner bottom surface of the pattern. This remaining liquid causes a consumption increase of the processing fluid and a reduction of a product yield. Accordingly, in the invention, the preliminary organic solvent supply processing is performed between the chemical processing and the rinse processing. Thus, even if the rinse liquid remains in the pattern, the rinse liquid remains not on the inner bottom surface of the pattern, but at a position sandwiched by two types of liquid layers in a vertical direction as shown in FIG. 7(b) to be described later. Out of these two types of liquid layers, the liquid layer on a vertically lower side is a layer of the organic solvent used in the preliminary organic solvent supply processing or a mixture layer of this organic solvent and the rinse liquid. Another liquid layer is a layer of the organic solvent used in the replacement processing or a mixture layer of this organic solvent and the rinse liquid. Therefore, the rinse liquid constituting the remaining liquid is diffused between the two liquid layers adjacent in the vertical direction and mixed with the organic solvent until the substrate in the liquid-filled state is conveyed to the supercritical processing device and contacted by the processing fluid in the supercritical state. As a result, a dry processing by the processing fluid in the supercritical state is performed in the absence of the remaining liquid on the inner bottom surface of the pattern, i.e. in a so-called remaining liquid-free state.

As described above, according to the invention, a supercritical dry processing can be performed in a remaining liquid-free state. As a result, a yield can be improved while the consumption of a processing fluid is reduced.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 is a drawing showing a schematic configuration of a first embodiment of a substrate processing system according to the present invention.

FIG. 2A is a side view showing the overall configuration of the wet processing device.

FIG. 2B is a diagram showing the operation of the wet processing device.

FIG. 3 is diagrams schematically showing the configuration and operation of the chuck pin.

FIG. 4 is a side view showing the configuration of the supercritical processing device.

FIG. 5 is a perspective view showing the structure of the support tray.

FIG. 6 is a flow chart outlining the processing performed by the substrate processing system according to the first embodiment.

FIG. 7 is a chart schematically showing differences in liquid film configuration due to the presence or absence of the preliminary organic solvent supply processing.

FIG. 8 is a chart showing a pressure change in the processing chamber.

FIG. 9 is a flow chart outlining a processing performed by a substrate processing system according to a second embodiment.

### DETAILED DESCRIPTION OF THE PREFERRED EMBODIMENTS

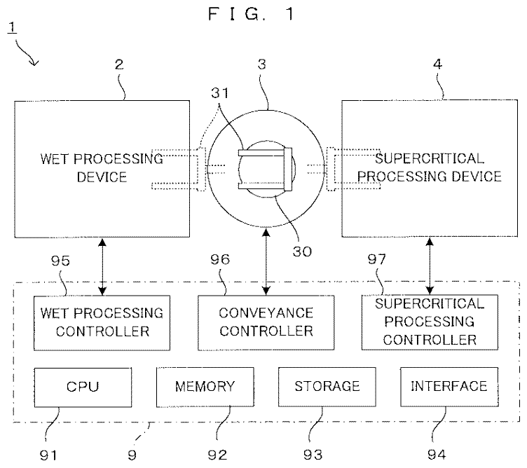

FIG. 1 is a drawing showing a schematic configuration of a first embodiment of a substrate processing system according to the present invention. This substrate processing system 1 is a processing system for wet-processing various substrates such as semiconductor wafers by supplying a processing fluid to the upper surfaces of the substrates and, thereafter, drying the substrates. The substrate processing system 1 has a suitable system configuration to carry out a substrate processing method according to the invention. That is, the substrate processing system 1 is provided with a wet processing device 2, a substrate conveying device 3 and a control device 9.

The wet processing device 2 performs a predetermined wet processing by receiving a substrate to be processed. Contents of the processing are not particularly limited. The wet processing includes a development processing and a cleaning processing of cleaning the substrate by a chemical, which processings are performed by the above conventional device, and a liquid-filled state filled with an organic solvent such as an IPA liquid is created on a pattern formed surface of the substrate. The substrate conveying device 3 carries out and conveys the substrate from the substrate processing device 2 with the liquid-filled state maintained, and carries the substrate into the supercritical processing device 4. The supercritical processing device 4 performs a dry processing (supercritical dry processing) using a processing fluid in a supercritical state for the carried-in substrate. These are installed in a clean room. Therefore, the substrate conveying device 3 conveys the substrate S in an air atmosphere and under an atmospheric pressure.

The control device 9 realizes a predetermined process by controlling these components of the device. For this purpose, the control device 9 includes a CPU 91, a memory 92, a storage 93, an interface 94, and the like. The CPU 91 executes various control programs. The memory 92 temporarily stores processing data. The storage 93 stores the control programs to be executed by the CPU 91. The interface 94 performs information exchange with a user and an external device. Operations of the device to be described later are realized by the CPU 91 causing each component of the device to perform a predetermined operation by executing the control program written in the storage 93 in advance.

The CPU 91 executes a predetermined control program, whereby functional blocks such as a wet processing controller 95 for controlling the operation of the wet processing device 2, a conveyance controller 96 for controlling the operation of the substrate conveying device 3 and a supercritical processing controller 97 for controlling the operation of the supercritical processing device 4 are realized by software in the control device 9. Note that each of these functional blocks may be at least partially configured by dedicated hardware.

Here, various substrates such as semiconductor wafers, glass substrates for photomask, glass substrates for liquid crystal display, glass substrates for plasma display, substrates for FED (Field Emission Display), optical disk substrates, magnetic disk substrates and magneto-optical disk substrates can be applied as the “substrate” in this embodiment. The substrate processing device used in processing semiconductor wafers is mainly described as an example with reference to the drawings below. However, application to the processing of various substrates illustrated above is also possible. Further, various shape of the substrate are also available.

A substrate S used as an example in the following description has a circuit pattern, etc. formed only on one main surface thereof. Here, a surface corresponding to the main surface with the circuit pattern, etc. will be called a “front surface,” and a main surface on the opposite side without a circuit pattern, etc. will be called a “back surface.” Furthermore, a surface of the substrate S facing downward will be called a “lower surface,” and a surface of the substrate S facing upward will be called an “upper surface.” In the example descried below, the front surface corresponds to the upper surface.

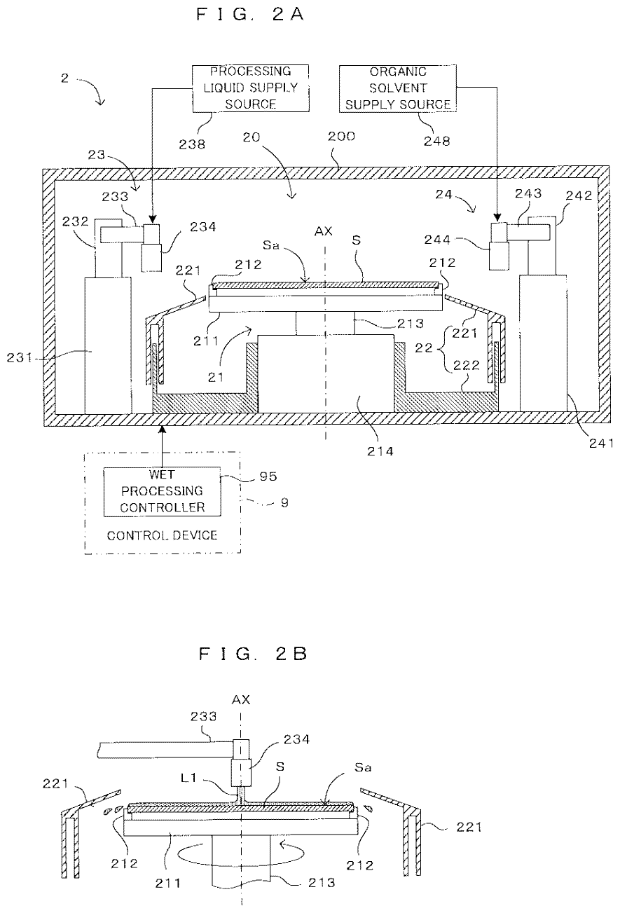

FIGS. 2A and 2B are diagrams showing a configuration example of the wet processing device. More specifically, FIG. 2A is a side view showing the overall configuration of the wet processing device, and FIG. 2B is a diagram showing the operation of the wet processing device. This wet processing device 2 is a device for processing the substrate by supplying the processing fluid to the upper surface of the substrate S. The operation of the wet processing device 2 is controlled by the wet processing controller 95 of the control device 9.

The wet processing device 2 performs a surface processing of the substrate S and performs various processes (chemical processing, preliminary organic solvent supply processing, rinse processing, replacement processing, and liquid film formation processing, etc.) that will be detailed later. For this purpose, the wet processing device 2 is provided with a substrate holder 21, a splash guard 22 and processing liquid suppliers 23, 24 inside the processing chamber 200. The operations of these are controlled by the wet processing controller 95 provided in the control device 9. The substrate holder 21 includes a disk-like spin chuck 211 having a diameter nearly equal to that of the substrate S, and a plurality of chuck pins 212 are provided on a peripheral edge part of the substrate S.

FIG. 3 is diagrams schematically showing the configuration and operation of the chuck pin, wherein FIG. 3(a) shows the chuck pin in a chucking state (sandwiching state) and FIG. 3(b) shows the chuck pin in a non-chucking state (releasing state). Although not shown, twelve chuck pins 212 are radially provided about an axis of rotation AX of the chuck pins 212 as a center in this embodiment. Each chuck pin 212 is arranged movably in a radial direction D on the upper surface of a peripheral edge part of the spin chuck 211. The “radial direction D” mentioned here means a longitudinal direction of a virtual line connecting the axis of rotation AX and the chuck pin 212.

Any of the plurality of chuck pins 212 has the same configuration. Accordingly, the configuration of one chuck pin 212 is described below and each part of the other chuck pins 212 is denoted by the same reference sign and not described. As shown in FIG. 3, the chuck pin 212 has a chuck contact surface 212a. This chuck contact surface 212a is movable along the radial direction D on the upper surface of the peripheral edge part of the spin chuck 211. In the chuck pin 212, a lower contact surface 212b is provided above the chuck contact surface 212a. The lower contact surface 212b is inclined downward in a (+D) direction toward the axis of rotation AX. A curved contact surface 212c is provided to extend upward from an end part of this lower contact surface 212b on a (−D) direction side. This curved contact surface 212c is finished into a curved surface facing toward the axis of rotation AX. Further, an upper contact surface 212d is provided to extend upward from an upper end of the curved contact surface 212c. This upper contact surface 212d is inclined upward in the (+D) direction toward the axis of rotation AX. More particularly, as shown in FIG. 3, the curved contact surface 212c is directly connected to the upper and lower contact surfaces 212d, 212b while being arranged between the upper and lower contact surfaces 212d, and 212b. Therefore, if a substrate contact part 212e, in which the upper contact surface 212d, the curved contact surface 212c and the lower contact surface 212b are connected and in contact with the substrate S, is viewed from a horizontal direction orthogonal to the radial direction D, the substrate contact part 212e is substantially C-shaped. That is, the chuck pin 212 is reciprocally movable along the radial direction D with the substrate contact part 212e facing the axis of rotation AX.

The chuck pin 212 is connected to a chuck driver 215. The chuck driver 215 moves the chuck pin 212 in the radial direction D in response to a command from the wet processing controller 95. For example, when the substrate S is transferred to the substrate conveying device 3, the chuck driver 215 moves the chuck pin 212 in the (−D) direction and positions the chuck pin 212 at the non-chucking position (corresponding to an example of a “releasing position” of the invention) as shown in FIG. 3(b). At this time, the curved contact surface 212c and the upper contact surface 212d are separated from the axis of rotation AX by a distance slightly longer than a radius of the substrate S. On the other hand, the lower contact surface 212b is located below the substrate S. Therefore, as shown in FIG. 3(b), the substrate S is supported at a position of the lower contact surface 212b separated toward the (+D) direction side from the curved contact surface 212c only by the lower contact surface 212b.

On the other hand, in chucking the substrate S, the chuck driver 215 moves the chuck pin 212 in the (+D) direction and positions the chuck pin 212 at the chucking position (corresponding to an example of a “sandwiching position” of the invention) as shown in FIG. 3(a). By moving the chuck pin 212 from the non-chucking position to the chucking position in this way, the support position of the substrate S by the lower contact surface 212b is shifted in the (−D) direction. When the movement of this chuck pin 212 to the chucking position is completed, the substrate S is supported by the lower contact surface 212b, the curved contact surface 212c and the upper contact surface 212d. That is, substrate chucking is completed.

In releasing the chucking of the substrate S, the chuck pin 212 is moved in a procedure reverse from the above procedure and the support position of the substrate S by the lower contact surface 212b is shifted in the (+D) direction.

Further, by moving the support position of the substrate S by the lower contact surface 212b in the radial direction D, the height position of the substrate S in a vertical direction Z is displaced by a distance dz. Accordingly, if the wet processing controller 95 gives a reciprocal movement command to the chuck driver 215, the chuck pin 212 is reciprocated in the radial direction D and lifting and lowering movements of the substrate S are synchronously repeated. That is, vibration in the vertical direction can be applied to the substrate S. In this embodiment, a chuck pin 212 capable of applying vibration is used, but a conventional chuck pin that does not have a vibration application function may be used.

Returning to FIGS. 2A and 2B, we continue with the explanation of the configuration of the wet processing device 2. The spin chuck 211 is so supported that the upper surface thereof is horizontal by a rotary support shaft 213 extending downward from a central part of the lower surface of the spin chuck 211. The rotary support shaft 213 is rotatably supported by a rotating mechanism 214 mounted in a bottom part of the processing chamber 200. The rotating mechanism 214 includes an unillustrated built-in rotary motor. The rotary motor rotates in response to a control command from the control device 9, whereby the spin chuck 211 directly coupled to the rotary support shaft 213 rotates about the axis of rotation AX indicated by a dashed-dotted line. In FIGS. 2A and 2B, an up-down direction is a vertical direction. In this way, the substrate S is rotated about the axis of rotation AX while being held in the horizontal posture.

The splash guard 22 is provided to laterally surround the substrate holder 21. The splash guard 22 includes a substantially tubular cup 221 provided to cover the peripheral edge part of the spin chuck 211 and a liquid receiver 222 provided below an outer peripheral part of the cup 221. The cup 211 is raised and lowered in response to a control command from the control device 9. The cup 221 is raised and lowered between a lower position where an upper end part of the cup 221 is lowered to below the peripheral edge part of the substrate S held by the spin chuck 211 as shown by solid lines in FIG. 3 and an upper position where the upper end part of the cup 221 is located above the peripheral edge part of the substrate S as shown by dotted lines in FIG. 3.

As shown by solid lines in FIG. 2A, when the cup 221 is at the lower position, the substrate S held by the spin chuck 211 is exposed to the outside of the cup 221. Thus, the cup 221 is, for example, prevented from becoming an obstacle when the substrate S is carried to and from the spin chuck 211.

Further, as indicated by dotted lines in FIG. 2B, the cup 221 surrounds the peripheral edge part of the substrate S held by the spin chuck 211 when being at the upper position. In this way, the processing liquid shaken off from the peripheral edge part of the substrate S during liquid supply to be described later is prevented from scattering in the chamber 200, and the processing liquid can be reliably collected. That is, by the rotation of the substrate S, droplets of the processing liquid shaken off from the peripheral edge part of the substrate S adhere to the inner wall of the cup 221, flow down and are finally gathered and collected by the liquid receiver 222 arranged below the cup 221. To individually collect a plurality of processing liquids, cups may be concentrically provided at a plurality of levels.

The processing liquid supplier 23 is structured such that a nozzle 234 is attached to the tip of an arm 233 horizontally extending from a rotary support shaft 232 provided rotatably with respect to a base 231 fixed in the processing chamber 200. The rotary support shaft 232 rotates in response to a control command from the control device 9, whereby the arm pivots and the nozzle 234 on the tip of the arm 233 moves between a retreated position (FIG. 2A) retracted laterally from above the substrate S and a processing position (FIG. 2B) above the substrate S.

The nozzle 234 is connected to a processing liquid supply source 238. If an appropriate processing liquid is sent out from the processing liquid supply source 238, the processing liquid is discharged toward the substrate S from the nozzle 234. By supplying the processing liquid L1 from the nozzle 234 positioned above a center of rotation of the substrate S while rotating the substrate S by the rotation of the spin chuck 211 at a relatively low speed, an upper surface Sa of the substrate S is processed by the processing liquid L1. Liquids having various functions such as chemicals (developers, etching liquids, cleaning liquids), rinsing liquids and the like can be used as the processing liquid, and a composition of the processing liquid is arbitrary. Further, the processing may be performed with a plurality of types of processing liquids combined.

Another processing liquid supplier 24 also has a configuration corresponding to the first processing liquid supplier 23 described above. That is, processing liquid supplier 24 includes a base 241, a rotary support shaft 242, an arm 243, a nozzle 244 and the like, and the configurations of these are the same as those of the corresponding components of the first processing liquid supplier 23. The rotary support shaft 242 rotates in response to a control command from the control device 9, whereby the arm 243 pivots. The nozzle 244 on the tip of the arm 243 supplies a processing liquid to the upper surface Sa of the substrate S.

In this wet processing device 2, the second processing liquid supplier 24 is used for the purpose of performing preliminary organic solvent supply processing, rinse processing, replacement processing, and liquid film formation processing. That is, the substrate S after the wet processing is conveyed to the supercritical processing device 4 and receives a supercritical drying processing. To prevent the surface of the substrate S from being exposed and oxidized during conveyance and prevent the collapse of the fine pattern formed on the surface, the substrate S is conveyed with the surface thereof covered with a puddle-like liquid film.

A substance having a lower surface tension than water, which is a main component of a processing liquid used in a cleaning processing, e.g. an organic solvent such as isopropyl alcohol (IPA) or acetone, is used as the liquid for constituting the liquid film. These organic solvents are supplied from an organic solvent supply source 248.

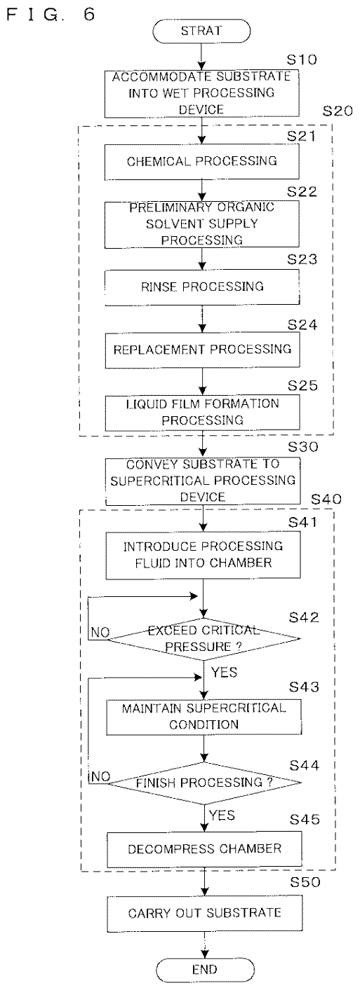

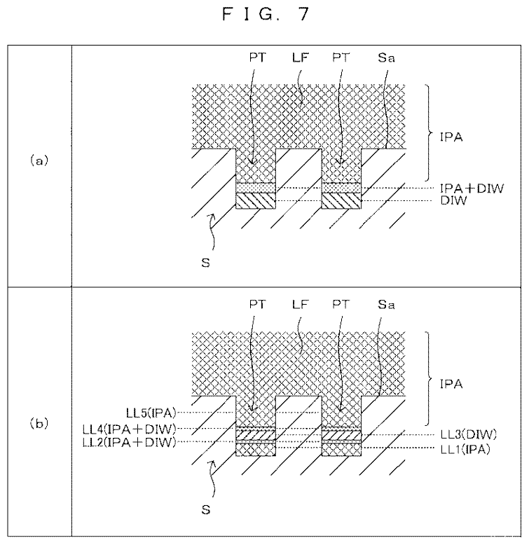

Further, in this embodiment, the organic solvent is supplied to the substrate S from the second processing fluid supplier 24 not only merely during the liquid film formation processing, but also during the preliminary organic solvent supply processing. This aims to remove the remaining liquid and is described in detail later with reference to FIGS. 6 and 7.

Although two processing liquid suppliers are provided in the wet processing device 2 here, the number, structures and functions of the processing liquid suppliers are not limited to these. For example, only one processing liquid supplier may be provided or three or more processing liquid suppliers may be provided. Further, one processing liquid supplier may include a plurality of nozzles. For example, a plurality of nozzles may be provided on the tip of one arm. Further, the processing liquid is not only discharged with the nozzle positioned at the predetermined position as described above, but also may be, for example, discharged while the nozzle is scanned and moved along the upper surface Sa of the substrate S.

Referring back to FIG. 1, description is continued. The substrate conveying device 3 is provided with a conveyor robot 30 provided with a hand 31 on the tip of a telescopic/rotatable arm. The hand 31 can support the substrate by partially contacting the lower surface of the substrate and, as shown by dotted lines in FIG. 1, is movable toward and away from both the wet processing device 2 and the supercritical processing device 4. In this way, the substrate can be carried in and out from each of the wet processing device 2 and the supercritical processing device 4. The operation of the conveyor robot 30 is controlled by the conveyance controller 96 of the control device 9. Many techniques are known as conveyor robots of this type. Since one of those can be appropriately selected and used also in this embodiment, detailed description is omitted.

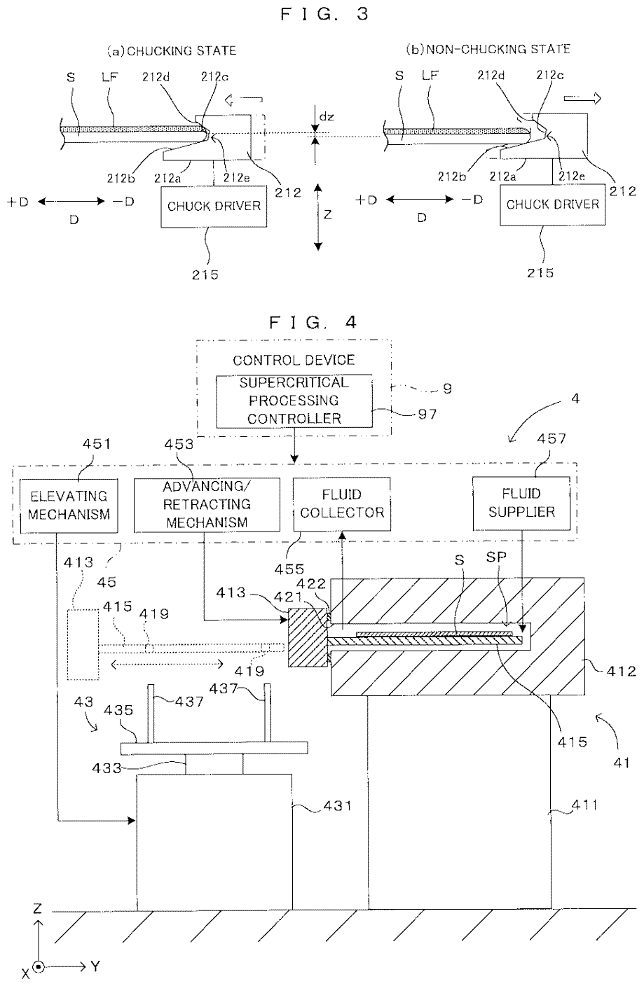

FIG. 4 is a side view showing the configuration of the supercritical processing device. The supercritical processing device 4 is a device for applying a drying processing using a processing fluid in a supercritical state to the substrate S after the wet processing. More specifically, the supercritical processing device 4 is a device for finally bringing the substrate S to a dry state by discharging the processing fluid after receiving the substrate S after the wet processing and replacing the liquid remaining on the substrate S by the processing fluid in the supercritical state.

The supercritical processing device 4 is provided with a processing unit 41 and a transfer unit 43 provided in the processing chamber 400 and a supply unit 45. The processing unit 41 serves as an executor of the supercritical drying processing. The transfer unit 43 receives the substrate S after the wet processing conveyed by the substrate conveying device 3, carries the substrate S into the processing unit 41 and transfers the processed substrate S from the processing unit 41 to the conveyor device 3. The supply unit 45 supplies chemical substances, power, energy and the like necessary for the processing to the processing unit 41 and the transfer unit 43. These operations are controlled by the control device 9, particularly by the supercritical processing controller 97.

The processing unit 41 is structured such that a processing chamber 412 is mounted on a pedestal 411. The processing chamber 412 is configured by a combination of several metal blocks and the inside thereof is hollow and constitutes a processing space SP. The substrate S to be processed is carried into the processing space SP and processed. A slit-like opening 421 elongated in the X direction is formed in a side surface on the (−Y) side of the processing chamber 412. The processing space SP and an outside space communicate via the opening 421. A cross-sectional shape of the processing space SP is substantially the same as an opening shape of the opening 421. That is, the processing space SP is a hollow having a cross-sectional shape long in the X direction and short in the Z direction and extending in the Y direction.

A lid member 413 is provided to close the opening 421 on a side surface on the (−Y) side of the processing chamber 412. The lid member 413 closes the opening 421 of the processing chamber 412, whereby an airtight processing container is configured. In this way, the substrate S can be processed under a high pressure in the processing space SP inside. A support tray 415 in the form of a flat plate is mounted in a horizontal posture on a side surface on the (+Y) side of the lid member 413. The upper surface of the support tray 415 serves as a support surface, on which the substrate S can be placed. The lid member 413 is supported horizontally movably in the Y direction by an unillustrated supporting mechanism.

The lid member 413 is movable toward and away from the processing chamber 412 by an advancing/retracting mechanism 453 provided in the supply unit 45. Specifically, the advancing/retracting mechanism 453 includes a linear motion mechanism such as a linear motor, a linear motion guide, a ball screw mechanism, a solenoid or an air cylinder. Such a linear motion mechanism moves the lid member 413 in the Y direction. The advancing/retracting mechanism 453 operates in response to a control command from the control device 9.

If the lid member 413 is separated from the processing chamber 412 by moving in the (−Y) direction and the support tray 415 is pulled out from the processing space SP to outside via the opening 421 as indicated by a dotted line, the support tray 415 becomes accessible. That is, the substrate S can be placed on the support tray 415 and the substrate S placed on the support tray 415 can be taken out. On the other hand, by a movement of the lid member 413 in the (+Y) direction, the support tray 415 is accommodated into the processing space SP. If the substrate S is placed on the support tray 415, the substrate S is carried into the processing space SP together with the support tray 415.

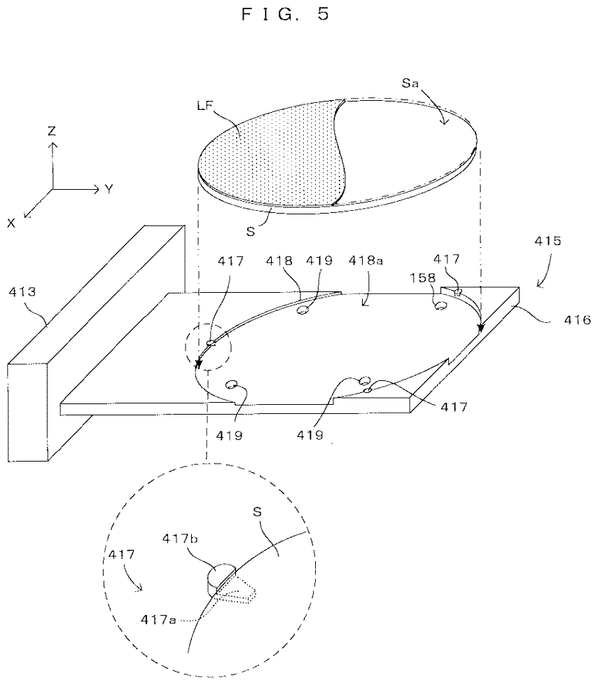

FIG. 5 is a perspective view showing the structure of the support tray. The support tray 415 includes a tray member 416 and a plurality of support pins 417. The tray member 415 is structured such that a recess 418 corresponding to the planar size of the substrate S, more specifically, having a diameter slightly larger than that of the circular substrate S, is provided in the horizontal and flat upper surface of a flat plate-like structure.

The recess 418 partially extends to the side surface of the tray member 416. That is, the side wall surface of the recess 48 is not circular, but partially cut. Thus, parts of a bottom surface 418a of the recess 418 are directly connected to the side surface in these cut parts. In this example, such cut parts are provided on both X side end parts and a (+Y) side end part of the support tray 415, and the bottom surface 418a is directly connected to the side surface in these parts.

Further, through holes 419, through which lift pins 437 are inserted, are perforated at positions of the bottom surface 418a corresponding to the lift pins 437 of the transfer unit 43. By lifting and lowering the lift pins 437 through the through holes 419, a state where the substrate S is accommodated in the recess 418 and a state where the substrate S is lifted up from the recess 418 are realized.

The plurality of support pins 417 are provided on a peripheral edge part of the recess 418. The number of the support pins 417 is arbitrary, but three or more support pins 417 are desirable to stably support the substrate S. In this embodiment, three support pins 417 are mounted on the tray member 416 to surround the bottom surface 418a in a plan view from above. As shown in a partial enlarged view in FIG. 5, the support pin 417 includes a height restricting part 417a and a horizontal position restricting part 417b.

The height restricting part 417a has a flat upper surface, and supports the substrate S and restricts the position of the substrate S in the vertical direction Z (hereinafter, referred to as a “height position”) by contacting a peripheral edge part of the lower surface of the substrate S. On the other hand, the horizontal position restricting part 417b extends further upward than the upper end of the height restricting part 417a and restricts the position of the substrate S in a horizontal direction (XY direction) by contacting the side surface of the substrate S. By such support pins 417, the substrate S are supported in a horizontal posture separated upward from the bottom surface 418a of the recess 418 while facing the bottom surface 418a.

The processing space SP is closed by the lid member 413 moving in the (+Y) direction and closing the opening 421. A sealing member 422 is provided between the side surface on the (+Y) side of the lid member 413 and the side surface on the (−Y) side of the processing chamber 412 to hold the processing space SP airtight. The sealing member 422 is, for example, made of rubber. Further, the lid member 413 is fixed to the processing chamber 412 by an unillustrated lock mechanism. As just described, in this embodiment, the lid member 413 is switched between a closing state (solid line) for sealing the processing space SP by closing the opening 421 and a separated state (dotted line) where the lid member 413 is largely separated from the opening 421 to enable the substrate S to be taken in and out.

With the airtight state of the processing space SP ensured, the substrate S is processed in the processing space SP. In this embodiment, a fluid supplier 457 provided in the supply unit 45 sends out a processing fluid of a substance usable in the supercritical processing, e.g. carbon dioxide, as the processing fluid and further brings the processing fluid into a supercritical state by pressurizing the processing fluid in the processing chamber 412. The processing fluid is supplied in a gas or liquid state to the processing unit 41. Carbon dioxide is a chemical substance suitable for the supercritical drying processing in having a property of entering the supercritical state at relatively low temperature and low pressure and dissolving into an organic solvent often used in substrate processing well. At a critical point at which carbon dioxide enters the supercritical state, an atmospheric pressure (critical pressure) is 7.38 MPa and a temperature (critical temperature) is 31.1° C.

If the processing fluid is filled into the processing space SP and the inside of the processing space SP reaches suitable temperature and pressure, the processing space SP is filled with the processing fluid in the supercritical state. In this way, the substrate S is processed by the processing fluid in the supercritical state in the processing chamber 412. The supply unit 45 is provided with a fluid collector 455, and the fluid after the processing is collected by the fluid collector 455. The fluid supplier 457 and the fluid collector 455 are controlled by the supercritical processing controller 97.

The processing space SP has a shape and a volume capable of receiving the support tray 415 and the substrate S supported by the support tray 415. That is, the processing space SP has a substantially rectangular cross-sectional shape wider than a width of the support tray 415 in a horizontal direction and having a height larger than that of the support tray 415 and substrate S combined in the vertical direction, and has a depth capable of receiving the support tray 415. As just described, the processing space SP has a shape and a volume enough to receive the support tray 415 and the substrate S. Gaps between the support tray 415 and the substrate S and the inner wall surface of the processing space SP are tiny. Therefore, the amount of the processing fluid necessary to fill the processing space SP can be relatively small.

The fluid supplier 457 supplies the processing fluid to the processing space SP on a side further in the (+Y) direction than the end part on the (+Y) side of the substrate S. On the other hand, the fluid collector 455 discharges the processing fluid flowing in a space above the substrate S and a space below the support tray 415, out of the processing space SP, on a side further in the (−Y) direction than the end part on the (−Y) side of the substrate S. In this way, laminar flows of the processing fluid from the (+Y) side toward the (−Y) side are respectively formed above the substrate S and below the support tray 415 in the processing space SP.

The supercritical processing controller 97 of the control device 9 specifies the pressure and temperature in the processing space SP based on a detection result of an unillustrated detector and controls the fluid supplier 457 and the fluid collector 455 based on that result. In this way, the supply of the processing fluid into the processing space SP and the discharge of the processing fluid from the processing space SP are properly managed and the pressure and temperature in the processing space SP are adjusted according to a processing recipe determined in advance.

The transfer unit 43 is in charge of the transfer of the substrate S between the substrate conveying device 3 and the support tray 415. For this purpose, the transfer unit 43 is provided with a body 431, an elevating member 433, a base member 435 and a plurality of lift pins 437. The elevating member 433 is a columnar member extending in the Z direction, and supported movably in the Z direction with respect to the body 431 by an unillustrated supporting mechanism. The base member 435 having a substantially horizontal upper surface is mounted atop the elevating member 433. The plurality of lift pins 437 stand up from the upper surface of the base member 435. The respective lift pins 437 support the substrate S in a horizontal posture from below by the contact of upper end parts thereof with the lower surface of the substrate S. Three or more lift pins 437 having the upper end parts at the same height are desirably provided to stably support the substrate S in the horizontal posture.

The elevating member 433 is made movable up and down by an elevating mechanism 451 provided in the supply unit 45. Specifically, the elevating mechanism 451 includes a linear motion mechanism such as a linear motor, a linear motion guide, a ball screw mechanism, a solenoid or an air cylinder, and such a linear motion mechanism moves the elevating member 433 in the Z direction. The elevating mechanism 451 operates in response to a control command from the control device 9.

The base member 435 is moved up and down by upward and downward movements of the elevating member 433, and the plurality of lift pins 437 move up and down integrally with the base member 435. In this way, the transfer of the substrate S is realized between the transfer unit 43 and the support tray 415. More specifically, as shown by dotted lines in FIG. 4, the substrate S is transferred with the support tray 415 pulled out to the outside of the chamber. For this purpose, the support tray 415 is provided with through holes 419, through which the lift pins 437 are inserted. If the base member 435 is raised, the upper ends of the lift pins 437 reach above the upper surface of the support tray 415 through the through holes 419. In this state, the substrate S conveyed by the conveyor robot 30 is transferred from the hand 31 of the conveyor robot 30 to the lift pins 437. By lowering the lift pins 437, the substrate S is transferred from the lift pins 437 to the support tray 415. The substrate S can be carried out by a procedure opposite to the above one.

FIG. 6 is a flow chart outlining the processing performed by the substrate processing system according to the first embodiment. This substrate processing system 1 receives a substrate S to be processed and successively performs the wet processing using processing liquids such as a chemical, a rinse liquid and an organic solvent, a conveyance processing of conveying the substrate S already subjected to the wet processing from the wet processing device 2 to the supercritical processing device 4 and the supercritical dry processing using a supercritical processing fluid. Specifically, the wet processing (Step S20), the conveyance processing (Step S30) and the supercritical dry processing (Step S40) are performed in this order if the substrate S to be processed is accommodated into the wet processing device 2 constituting the substrate processing system 1.

Here, the substrate S may be directly carried in by an external conveying device or may be carried in from the external conveying device via the conveyor robot 30.

The wet processing device 2 applies the wet processing to the substrate S using predetermined processing liquids (Step S20). In this wet processing, the preliminary organic solvent supply processing (Step S22) of suppling the organic solvent is performed in addition to the conventional chemical processing (Step S21), rinse processing (Step S23), replacement processing (Step S24) and liquid film formation processing (Step S25). The preliminary organic solvent supply processing is performed between the chemical processing and the rinse processing. That is, in the wet processing, the organic solvent such as IPA or acetone is, for example, supplied to the surface Sa of the substrate S (Step S22) after the predetermined chemical processing is performed by supplying the chemical such as a developer or a cleaning liquid in Step S21. Subsequent to that, the rinse liquid such as DIW (de-ionized water) is supplied to the surface Sa of the substrate S and, further, the organic solvent such as the IPA is, for example, supplied to the substrate S, whereby the rinse liquid adhering to the surface Sa of the substrate S is replaced by the organic solvent (Step S24) and a liquid-filled state filled with the organic solvent is created. That is, a liquid film LF is formed on the surface Sa of the substrate S (Step S25: liquid film formation processing).

Here, the technical significance of the liquid film formation processing and the preliminary organic solvent supply processing is described with reference to FIG. 7. FIG. 7 is a chart schematically showing differences in liquid film configuration due to the presence or absence of the preliminary organic solvent supply processing, wherein field (a) of FIG. 7 shows a conventional technique in which the preliminary organic solvent supply processing is not performed and field (b) shows the embodiment in which the preliminary organic solvent supply processing is performed. For example, if the DIW is present in a pattern PT formed in the surface Sa of the substrate S, there is a possibility that the pattern PT collapses due to a surface tension of the DIW. Further, water marks may remain on the surface Sa of the substrate S due to incomplete drying. Furthermore, the surface Sa of the substrate S may undergo deterioration such as oxidation by being exposed to outside air. To avoid such a problem, the surface Sa of the substrate S is covered with the organic solvent. A liquid having a lower surface tension than the DIW and low in corrosivity to the substrate S, e.g. a liquid compatible with the DIW such as IPA and acetone, is suitably used as the organic solvent. A case where the DIW is used as the rinse liquid and the IPA is used as the organic solvent is described below.

Here, if replacement into the IPA is satisfactorily performed, the liquid film LF is made of only the IPA or a mixture of the IPA and the DIW. In this case, the DIW does not remain on the inner bottom surface of the pattern PT. However, in reality, the remaining liquid (DIW) may remain on the inner bottom surface of the pattern PT as shown FIG. 7(a) in a conventional example. A specific gravity of this remaining liquid is larger than that of the organic solvent and the remaining liquid easily remains on the inner bottom surface of the pattern PT.

Accordingly, in this embodiment, the IPA is supplied to the surface Sa of the substrate S between the chemical processing (Step S21) and the rinse processing (Step S22). In this way, the following five liquid layers LL1 to LL5 are successively laminated from the inner bottom surface side in the pattern PT:

Liquid layer LL1 is an IPA layer made of the IPA used in the preliminary organic solvent supply processing,

Liquid layer LL2 is a mixture layer of the IPA used in the preliminary organic solvent supply processing and the DIW,

Liquid layer LL3 is a layer of the remaining liquid made of the DIW,

Liquid layer LL4 is a mixture layer of the IPA used in the replacement processing and the DIW, and

Liquid layer LL5 is an IPA layer made of the IPA used in the replacement processing. Note that part of the IPA used in the liquid film formation processing may be contained in the liquid layer LL5.

As just described, the liquid layer LL3, i.e. the remaining liquid (DIW), in the pattern PT is present in a state sandwiched between the liquid layers LL2 and LL4 containing the IPA. The DIW constituting the remaining liquid is diffused between the liquid layers LL2 and LL4 during conveyance to the supercritical processing device 4 by the substrate conveying device 3 as described next. As a result, the liquid layer LL3 made of only the remaining liquid is removed. In this way, the liquid film LF free from the remaining liquid is formed on the surface Sa of the substrate S. Then, the substrate S is conveyed from the wet processing device 2 to the supercritical processing device 4 by the substrate conveying device 3 while being kept in the liquid-filled state (Step S30).

The substrate S conveyed to the supercritical processing device 4 is accommodated into the processing chamber 412 while being kept in the liquid-filled state. Specifically, the substrate S is conveyed with the pattern formed surface (surface Sa) faced up and covered with the thin liquid film LF. As shown by dotted lines in FIG. 4, the lift pins 437 are lifted with the lid member 413 moved to the (−Y) side and the support tray 415 pulled out. The conveying device transfers the substrate S to the lift pins 437. By lowering the lift pins 437, the substrate S is placed on the support tray 415. If the support tray 415 and the lid member 413 integrally move in the (+Y) direction, the support tray 415 supporting the substrate S is accommodated into the processing space SP in the processing chamber 412 and the opening 421 is closed by the lid member 413.

In this state, carbon dioxide serving as the processing fluid is introduced in a gas phase state into the processing space SP (Step S106). Outside air enters the processing space SP when the substrate S is carried in. By introducing the processing fluid in a gas phase, the outside air can be replaced. By injecting the processing fluid in the gas phase, a pressure in the processing chamber 412 is increased.

Note that the processing fluid is continuously discharged from the processing space SP in the process of introducing the processing fluid. That is, the processing fluid is discharged from the processing space SP by the fluid collector 455 also while the processing fluid is introduced by the fluid supplier 457. In this way, the processing fluid used for the processing is discharged into the processing space SP without staying, and impurities such as residues taken into the processing fluid are prevented from re-adhering to the substrate S.

If a supply amount of the processing fluid is more than a discharge amount, a density of the processing fluid in the processing space SP increases and a chamber inner pressure increases. Conversely, if the supply amount of the processing fluid is less than the discharge amount, the density of the processing fluid in the processing space SP decreases and the chamber inner pressure decreases. The processing fluid is supplied into and discharged from the processing chamber 412 based on a supply/discharge recipe prepared in advance. That is, the control device 9 adjusts supply/discharge timings, a flow rate and the like of the processing fluid by controlling the fluid supplier 457 and the fluid collector 455 based on the supply/discharge recipe.

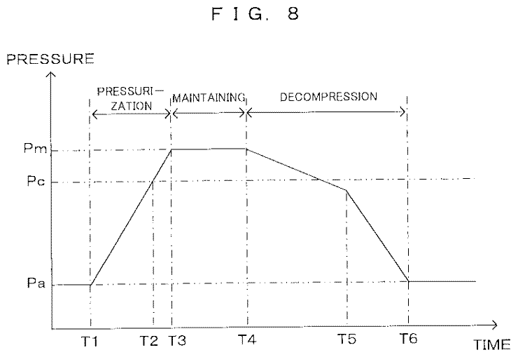

FIG. 8 is a chart showing a pressure change in the processing chamber. If the processing fluid is carbon dioxide, a temperature change during the processing is not very large since a critical temperature of the processing fluid is not very different from a room temperature. Here, a phenomenon is described, focusing on the chamber inner pressure, which notably changes. The introduction of the processing fluid is started and the internal pressure starts to increase at time T1 after the processing space SP is closed from a state where the processing space SP is open to atmospheric air and the internal pressure is an atmospheric pressure Pa.

Pressurization is continued until the pressure of the processing fluid increases in the processing space SP and exceeds a critical pressure Pc in the processing space SP (Step S42). At time T2 at which the critical pressure Pc is reached in the chamber, the processing fluid enters the supercritical state in the chamber. That is, the processing fluid transitions from the gas phase to the supercritical state due to a phase change in the processing space SP. By filling the processing space SP with the processing fluid in the supercritical state, the IPA (or mixed fluid of the IPA and the DIW) covering the substrate is replaced by the processing fluid in the supercritical state. The IPA and the like liberated from the surface of the substrate S is discharged from the processing chamber 412 together with the processing fluid while being dissolved in the processing fluid, and removed from the substrate S. That is, the processing fluid in the supercritical state has a function of replacing the IPA (or mixed fluid of the IPA and the DIW) adhering to the substrate S and serving as a liquid to be replaced, and discharging the liquid to be replaced to the outside of the processing chamber 412.

By continuing a state where the processing space SP is filled with the processing fluid in the supercritical state for a predetermined time after time T3 at which the processing fluid has reliably transitioned into the supercritical state (Steps S43, S44), the liquid to be replaced adhering to the substrate S can be completely replaced and discharged to the outside of the chamber. Note that although a chamber inner pressure Pm in the supercritical state is shown to be constant in FIG. 7, the pressure may fluctuate within such a range as not to fall to or below the critical pressure Pc.

If the replacement of the liquid to be replaced by the processing fluid in the supercritical state is finished in the processing chamber 412 at time T4 (“YES” in Step S44), the processing fluid in the processing space SP is discharged and the substrate S is dried. Specifically, the inside of the processing chamber 12 filled with the processing fluid in the supercritical state is decompressed by increasing the discharge amount of the fluid from the processing space SP (Step S45).

In a decompression process, the supply of the processing fluid may be stopped or a small amount of the processing fluid may be continuously supplied. By decompression from the state where the processing space SP is filled with the processing fluid in the supercritical state, the phase of the processing fluid changes from the supercritical state to the gas phase. By discharging the vaporized fluid to outside, the substrate S is dried. At this time, a decompression rate is so adjusted that a solid phase and a liquid phase are not created due to a sudden temperature drop. That is, decompression is performed at a relatively low decompression rate until time T5 at which the pressure reliably falls below the critical pressure Pc after decompression is started at time T4. In this way, the processing fluid in the processing space SP is directly vaporized from the supercritical state and discharged to outside.

At and after time T5 at which the processing fluid is completely vaporized, the decompression rate is increased, whereby decompression to the atmospheric pressure Pa is possible in a short time. By doing so, the processing fluid is not liquefied and the formation of a gas/liquid interface on the substrate S having the surface exposed after drying is avoided for an entire period from time T4 at which decompression is started to time T6 at which the pressure in the chamber falls to the atmospheric pressure Pa.

As just described, in the supercritical dry processing of this embodiment, the liquid adhering to the substrate can be efficiently replaced and prevented from remaining on the substrate S by changing the phase of the processing fluid to the gas phase and discharging the processing fluid after the processing space SP is filled with the processing fluid in the supercritical state. Moreover, the substrate can be dried while avoiding problems caused by the formation of the gas/liquid interface such as the contamination of the substrate and pattern collapse due to the adhesion of impurities.

The processed substrate S is delivered to a post-process (Step S50). That is, the support tray 415 is pulled out from the processing chamber 412 by moving the lid member 413 in the (−Y) direction, and the substrate S is transferred to the external conveying device via the transfer unit 43. At this time, the substrate S is in a dry state. Contents of the post-process are arbitrary. In this way, the processing for one substrate S is completed. If there is a substrate to be processed next, return is made to Step S10, a new substrate S is received and the above processing is repeated.

As described above, according to the first embodiment, the preliminary organic solvent supply processing (Step S22), the rinse processing (Step S23), the replacement processing (Step S24) and the liquid film formation processing (Step S25) corresponding to an example of a “liquid fill processing” of the invention are performed in this order after the chemical processing (Step S21) in the wet processing device 2. Here, even if the DIW remains in the pattern PT in the pattern formed surface (surface Sa) of the substrate S in the liquid-filled state, the liquid layer LL3 made of the remaining liquid is sandwiched by the liquid layers LL2 and LL4, which are the mixture layers of the IPA and the DIW, in the vertical direction as shown in FIG. 7(b). Thus, the DIW constituting the liquid layer LL3 is diffused between the liquid layers LL2 and LL4. Particularly, there is a sufficient time for the mutual diffusion of the remaining liquid (DIW) between the liquid layers LL2 and LL4 until the substrate S in the liquid-filled state is conveyed to the supercritical processing device 4 and contacted by the processing fluid in the supercritical state. From this, the remaining liquid is mixed into the IPA by the mutual diffusion. Therefore, the dry processing by the processing fluid in the supercritical state is performed in a so-called remaining liquid-free state. This means that the supercritical dry processing is performed in high quality without excessively using the processing fluid in the supercritical state. As a result, a yield can be improved while the consumption of the processing fluid is reduced.

As described above, in the first embodiment, the DIW corresponds to an example of a “rinse liquid” of the invention. Further, the IPA corresponds to an example of an “organic solvent” of the invention, and is used as the “organic solvent” in the preliminary organic solvent supply processing (Step S22), the replacement processing (Step S24) and the liquid film formation processing (Step S25). The surface Sa of the substrate S corresponds to an example of a “pattern formed surface” of the invention. Further, Steps S20, S30 and S40 respectively correspond to examples of a “operation (a)”, a “operation (b)” and a “operation (c)” of the invention.

In the first embodiment, the substrate S is conveyed from the wet processing device 2 to the supercritical processing device 4 while having a so-called sandwich structure of sandwiching the liquid layer LL3 corresponding to the remaining liquid by the liquid layers LL2, LL4. Here, vibration may be applied to the substrate S before and/or during conveyance and/or before the supply of the processing fluid in the supercritical processing device 4. By this vibration application, the mutual diffusion of the DIW constituting the liquid layer LL3 and the liquid layers LL2, LL4 is promoted and the remaining liquid can be removed in a shorter time.

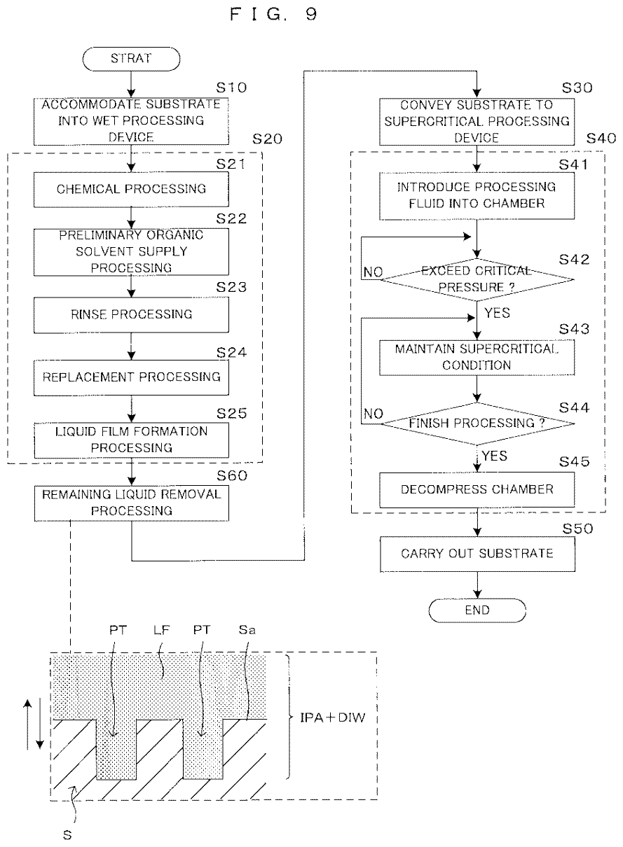

FIG. 9 is a flow chart outlining a processing performed by a substrate processing system according to a second embodiment. In the first embodiment, the chuck pins 212 have the vibration application function besides the function of sandwiching the side edge part of the substrate S and holding the substrate S. Accordingly, in the second embodiment, vibration may be applied to the substrate S (Step S60) after the liquid film formation processing (Step S25) and before the substrate conveyance (Step S30), for example, as shown in FIG. 9. More specifically, the wet processing controller 95 gives a reciprocal movement command to the chuck driver 215 after the liquid-filled state is created in the wet processing device 2. Then, the chucking state shown in FIG. 3(a) and the non-chucking state shown in FIG. 3(b) are alternately repeated. That is, lifting and lowering movements of the substrate S are repeated as the chuck pins 212 are reciprocated in the radial direction D. In this way, vibration in the vertical direction Z is applied to the substrate S as shown in a left lower figure of FIG. 9 and the remaining liquid (DIW) constituting the liquid layer LL3 is transferred and diffused into the liquid layers LL2, LL4 and the DIW contained in the liquid layers LL2, LL4 are also transferred and diffused into each of the liquid layers LL1, LL5. In this way, the liquid layer LL3 disappears in a shorter time than in the first embodiment and the DIW spreads in the entire liquid film LF (Step S60). Note that, in this specification, a processing of removing the remaining liquid by vibration application in this way is called a “remaining liquid removal processing”.

Further, in the second embodiment, the vibration application function is essential to perform the remaining liquid removal processing. The chuck pins 212 provide that function. Thus, it is not necessary to add a configuration dedicated to the vibration application function, wherefore device cost can be reduced.

Note that although the substrate S is vibrated in the vertical direction Z to perform the remaining liquid removal processing in the second embodiment, a vibration application mode is not limited to this. For example, the wet processing controller 95 may give a forward/reverse rotation command to the rotating mechanism 214 with the substrate S held by the chuck pins 212. In this case, the rotating mechanism 214 having received the forward/reverse rotation command repeats an operation of rotating the substrate S forward and backward by a predetermined angle about the axis of rotation AX, i.e. a pivoting operation. In this way, vibration may be applied to the substrate S by the operation of pivoting the substrate S in a circumferential direction.

Further, vibration may be applied to the substrate S by a separately added configuration without applying vibration along the vertical direction Z by the chuck pins 212 (hereinafter, referred to as “vertical vibration application”) or applying vibration along the circumferential direction by the rotating mechanism 214 (hereinafter, referred to as “pivot vibration application”). For example, following the liquid film formation processing (Step S25), the wet processing controller 95 may actuate an ultrasonic vibrator installed at a position separated from the substrate holder 21 and vibrate the substrate S by ultrasonic waves generated by the ultrasonic vibrator (third embodiment). Further, a vibrator may be mounted in the substrate holder 21 in advance, and the wet processing controller 95 may actuate the vibrator, following the liquid film formation processing (Step S25). In these embodiments, a vibration direction of the substrate S can be controlled by a vibrator installation mode. Note that conventionally known ones can be used as the vibrator and the ultrasonic vibrator. Therefore, the detailed configurations are not described in this specification.

Although vibration is applied to the substrate S in the liquid-filled state in the wet processing device 2 in the above second embodiment, vibration may be applied in the substrate conveying device 3 or the supercritical processing device 4. For example, in the first and second embodiments, the conveyor robot 30 is movable toward and away from both the wet processing device 2 and the supercritical processing device 4 while supporting the substrate S in the liquid-filled state from below. Therefore, the conveyor robot 30 can not only carry the substrate S in and out from each of the wet processing device 2 and the supercritical processing device 4, but also reciprocate and rotate the hand 31 supporting the substrate S in the horizontal direction. That is, vibration along the horizontal direction can be applied to the substrate S by repeating the reciprocal movements and pivoting of the hand 31. Thus, the conveyance controller 96 controls the conveyor robot 30 so that the conveying step (Step S30) from the wet processing device 2 to the supercritical processing device 4 may include the following three sub-steps:
a sub-step of receiving the substrate S in the liquid-filled state;
a sub-step of applying vibration to the substrate S by reciprocating the hand 31 by a predetermined distance in a horizontal plane and rotating the hand 31 in forward and reverse directions while holding the substrate S in the liquid-filled state; and
a sub-step of conveying the substrate in the liquid-filled state to the processing unit 41 of the supercritical processing device 4 as in the first embodiment. Although the remaining liquid removal processing is performed when the hand 31 enters the wet processing device 2 and receives the substrate S in the liquid-filled state in the fifth embodiment, an execution timing of the remaining liquid removal processing is not limited to this. For example, the remaining liquid removal processing may be performed while the hand 31 is moving to the supercritical processing device 4 or while the hand 31 is waiting on standby near the supercritical processing device 4.

Further, to wait the conveyance of the substrate S to the supercritical processing device 4 according to an operational status of the supercritical processing device 4, another standby position may be provided, besides the setting of the standby position near the supercritical processing device 4 as described above. For example, if the substrate conveying device 3 includes a mounting table, on which the substrate S in the liquid-filled state is temporarily placed and waits on standby, this mounting table functions as a standby position. Therefore, a vibrator may be mounted in this mounting table and vibration may be applied to the substrate S waiting on standby on the mounting table. That is, the remaining liquid removal processing may be performed at the standby position where the mounting table is provided.

Further, although the hand 31 is vibrated along the horizontal direction or pivoted in the horizontal plane to perform the remaining liquid removal processing in the fifth embodiment, vibration may be given in another mode depending on the configuration of the conveyor robot 30. For example, the conveyor robot 30 may be configured to be able to move the hand 31 in the vertical direction Z. In such a case, the substrate S may be vibrated by lifting and lowering the hand 31 holding the substrate S in the liquid-filled state in the vertical direction Z. Further, as in the third and fourth embodiments, the hand 31 may be vibrated.

In the first and second embodiments, the substrate S conveyed to the supercritical processing device 4 is accommodated into the processing chamber 412 while being kept in the liquid-filled state. Specifically, the substrate S is conveyed with the pattern formed surface faced up and covered with a thin liquid film LF. As shown by dotted lines in FIG. 4, the lift pins 437 are lifted with the lid member 413 moved to the (−Y) side and the support tray 415 pulled out. The conveying device transfers the substrate S to the lift pins 437. By lowering the lift pins 437, the substrate S is placed on the support tray 415. In this way, the reception of the substrate S is completed.

At this point of time, the supercritical processing controller 97 may reciprocate the support tray 415 and the lid member 41 along the Y direction while holding the substrate S in the liquid-filled state. By applying vibration to the substrate S by these reciprocal movements, the remaining liquid is transferred and diffused (remaining liquid removal processing) as in the second embodiment. According to the this embodiment, the remaining liquid removal processing is performed in the supercritical processing device 4 before the processing fluid in the supercritical state is brought into contact with the substrate S. Accordingly, the same effect as in the second embodiment is obtained.

Although the support tray 415 and the lid member 413 are vibrated along the Y direction to perform the remaining liquid removal processing in the this embodiment, a vibrator may be mounted in the support tray 415 or the lid member 413. That is, the substrate S may be vibrated by actuating the vibrator in response to a vibration command from the supercritical processing controller 97.

Further, although the remaining liquid removal processing is performed before the pressure in the processing chambers 412 increases, the remaining liquid removal processing may be performed during a pressure increase before critical conditions are reached. For example, the remaining liquid removal processing may be performed in a subcritical state. Particularly, if an elapsed time from the execution of the remaining liquid removal processing to the start of contact with the processing fluid in the supercritical state is considered, the remaining liquid removal processing is preferably performed at a timing close to the subcritical state. That is, there is a possibility that, as the elapsed time becomes longer, such as due to a specific gravity of the DIW larger than that of the IPA, part of the DIW diffused into the IPA precipitates to the inner bottom surface of the pattern PT to increase a DIW concentration. The execution timing of the remaining liquid removal processing is preferably set in view of this point.

Further, a step of warming the inside of the pattern may be provided instead of or besides the vibration application. For example, at least one of the following measures may be performed:
(a) Use a rinse liquid having a temperature of equal to or higher than 40° C. and equal to or lower than an upper limit temperature capable of maintaining the liquid-filled state,
(b) Supply high-temperature DIW or heated fluid (these are collectively referred to as “heating medium”) to a back surface Sb of the substrate S opposite to the pattern formed surface Sa in parallel to the liquid film formation processing (liquid fill processing), wherein the heating medium preferably has a temperature equal to or higher than 80° C. and equal to or lower than an upper limit temperature capable of maintaining the liquid-filled state,
(c) Heat the substrate S by a heater (not shown) arranged to face the back surface Sb of the substrate S opposite to the pattern formed surface Sa in parallel to the liquid film formation processing (liquid fill processing),
(d) Transfer the substrate S to the supercritical processing device 4 by the hand 31 while heating the substrate S received from the wet processing device 2 by a heater (not shown) provided in the hand 31 of the conveyor robot 30, and
(e) Heat the substrate S by a heater (not shown) provided in the support tray 415 before the substrate is dried by bringing the processing fluid in the supercritical state into contact with the substrate in the supercritical processing device 4.

Note that the invention is not limited to the above embodiments and various changes other than the aforementioned ones can be made without departing from the gist of the invention. In the above embodiments, the IPA is used as the organic solvent in any of the preliminary organic solvent supply processing (Step S22), the replacement processing (Step S24) and the liquid film formation processing (Step S25). However, a combination of the organic solvents used in the respective processings is not limited to this and a plurality of types of organic solvents may be combined. For example, acetone may be used in one of these three processings, whereas the IPA may be used in the remaining processings.

Further, various chemical substances used in the processings of the above embodiments are some examples, and various others can be used if these are consistent with the technical concept of the invention described above.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

This invention can be applied to substrate processing methods and substrate processing systems in general for processing a substrate covered with a liquid film by a processing fluid in a supercritical state.

What is claimed is:

1. A substrate processing method for processing a substrate having a pattern formed surface formed with a pattern, the method comprising:
(a) performing a chemical processing of the substrate by supplying a chemical to the pattern formed surface, a preliminary organic solvent supply processing by supplying an organic solvent to the pattern formed surface, a rinse processing by supplying a rinse liquid to the pattern formed surface, a replacement processing by supplying the organic solvent to the pattern formed surface and a liquid fill processing by supplying the organic solvent on the pattern formed surface in this order in a wet processing device;
(b) conveying the substrate from the wet processing device to a supercritical processing device while a liquid-filled state of the organic solvent on the pattern formed surface by the liquid fill processing is kept; and
(c) drying the substrate by bringing a processing fluid in a supercritical state into contact with the pattern formed surface in the liquid-filled state in the supercritical processing device.

2. The substrate processing method according to claim 1, wherein:
the organic solvent used in the preliminary organic solvent supply processing, the organic solvent used in the replacement processing and the organic solvent used in the liquid fill processing are of the same type.

3. The substrate processing method according to claim 2, wherein:
the organic solvent used in the preliminary organic solvent supply processing, the organic solvent used in the replacement processing and the organic solvent used in the liquid fill processing are isopropyl alcohol (IPA).

4. The substrate processing method according to claim 1, further comprising:
(d) mixing the rinse liquid remaining in the pattern with the organic solvent by applying vibration to the substrate while the liquid-filled state is maintained before the processing fluid in the supercritical state is brought into contact with the pattern formed surface.

5. The substrate processing method according to claim 1, wherein:
inside of the pattern is warmed while the liquid-filled state is maintained in at least one of the operation (a), the operation (b) and the operation (c).

6. A substrate processing system for processing a substrate having a pattern formed surface formed with a pattern, the system comprising:
a wet processing device configured to perform a chemical processing, a preliminary organic solvent supply processing, a rinse processing, a replacement processing and a liquid fill processing in this order, the chemical processing being of supplying a chemical to the pattern formed surface, the preliminary organic solvent supply processing being of supplying an organic solvent to the pattern formed surface, the rinse processing being of supplying a rinse liquid to the pattern formed surface, the replacement processing being of supplying the organic solvent to the pattern formed surface, the liquid fill processing being of creating a liquid-filled state filled with the organic solvent on the pattern formed surface;
a supercritical processing device configured to dry the substrate by bringing a processing fluid in a supercritical state into contact with the pattern formed surface in the liquid-filled state; and
a substrate conveying device configured to convey the substrate in the liquid-filled state from the wet processing device to the supercritical processing device.
